(19) United States
(12) Patent Application Publication
(10) Pub. No.: US 2020/0083473 A1
(43) Pub. Date: Mar. 12, 2020

(54) OLED DISPLAY SUBSTRATE AND A METHOD FOR PREPARING THE SAME, AND AN OLED DISPLAY DEVICE

(71) Applicant: BOE TECHNOLOGY GROUP CO., LTD., Beijing (CN)

(72) Inventor: Pengfei GU, Beijing (CN)

(21) Appl. No.: 16/398,165

(22) Filed: Apr. 29, 2019

(30) Foreign Application Priority Data
Sep. 11, 2018 (CN) 201811057936.2

(51) Int. Cl. H01L 51/52; G09G 3/3225; H01L 27/32

(52) U.S. Cl. CPC H01L 51/5203; H01L 27/3244; G09G 3/3225

(57) ABSTRACT

An OLED display substrate and a method of preparing the same, and an OLED display device are provided, the OLED display substrate including: a base substrate; an OLED device layer above the base substrate; and a photosensitive structure layer between the base substrate and the OLED device layer; the photosensitive structure layer is configured to convert an optical energy of light rays incident on the OLED display substrate into an electric energy, and in turn to provide the OLED device layer with the electric energy to drive the OLED device layer to emit light rays, and to use a luminance displayed by the the OLED device layer of the OLED display substrate to indicate an intensity of the light rays which are irradiating onto the OLED display substrate.

### CROSS-REFERENCE TO RELATED APPLICATION

The present disclosure claims the benefit of Chinese Patent Application Invention No. 201811057936.2 filed on Sep. 11, 2018 in the State Intellectual Property Office of China, the whole disclosure of which is incorporated herein by reference.

### BACKGROUND

### Field

Embodiments of the present disclosure generally relate to the technical field of display technology, and in particular, to an OLED display substrate and a method for preparing the same, and an OLED display device.

### Description of the Related Art

After research, it is found that, it is required to further improve OLED display devices in a relevant art to indicate intensity of outdoor ultraviolet or visible light, and in turn to intuitively alert users to take precautions against light pollution caused by ultraviolet or visible light having an excessive large intensity, so as to avoid any adverse influence applied by an excessive light radiation due to light pollution onto human life and production environment and even harm to human health.

### SUMMARY

The embodiments of the present disclosure have been made to overcome or alleviate at least one aspect of the above mentioned disadvantages and/or shortcomings in the prior art, by providing an OLED display substrate and a method for preparing the same, and an OLED display device, so as to indicate intensity of outdoor light rays to intuitively alert to take precautions.

Following technical solutions are adopted in exemplary embodiments of the invention.

According to one aspect of embodiments of the disclosure, there is provided an OLED display substrate, comprising: a base substrate; an OLED device layer above the base substrate; and a photosensitive structure layer between the base substrate and the OLED device layer; the photosensitive structure layer is configured to convert an optical energy of light rays incident on the OLED display substrate into an electric energy, and in turn to provide the OLED device layer with the electric energy to drive the OLED device layer to emit light rays, and to use a luminance displayed by the the OLED device layer of the OLED display substrate to indicate an intensity of the light rays which are irradiating onto the OLED display substrate.

According to an exemplary embodiment of the present disclosure, the photosensitive structure layer comprises: a first electrode on a side of the base substrate; a photosensitive layer on a side of the first electrode facing away from the base substrate; and a second electrode on a side of the photosensitive layer facing away from the base substrate.

According to an exemplary embodiment of the present disclosure, the photosensitive layer further comprises: a first photosensitive sub-layer; and a second photosensitive sub-layer on a side of the first photosensitive sub-layer facing away from or facing towards the base substrate.

According to an exemplary embodiment of the present disclosure, the OLED device layer comprises: a third electrode, the third electrode being formed on a side of the photosensitive structure layer facing away from the base substrate; a fourth electrode above a side of the third electrode facing away from the base substrate; and an organic light-emitting layer between the third electrode and the fourth electrode.

According to an exemplary embodiment of the present disclosure, each of an orthographic projection of the first photosensitive sub-layer on the base substrate and an orthographic projection of the second photosensitive sub-layer on the base substrate coincides with an orthographic projection of the first electrode on the base substrate, and an orthographic projection of the fourth electrode on the base substrate coincides with an orthographic projection of the first electrode on the base substrate.

According to an exemplary embodiment of the present disclosure, a material for preparing the first photosensitive sub-layer is a n-type semiconductor material, and a material for preparing the second photosensitive sub-layer is a p-type semiconductor material.

According to an exemplary embodiment of the present disclosure, the n-type semiconductor material comprises zinc oxide; and the p-type semiconductor material comprises gallium nitride.

According to an exemplary embodiment of the present disclosure, the n-type semiconductor material comprises n-type amorphous silicon; and the p-type semiconductor material comprises p-type amorphous silicon.

According to an exemplary embodiment of the present disclosure, the OLED display substrate comprises a first display area and a second display area; the n-type semiconductor material located within the first display area comprises zinc oxide, and the p-type semiconductor material located within the first display area comprises gallium nitride; the n-type semiconductor material located within the second display area comprises n-type amorphous silicon, and the p-type semiconductor material located within the second display area comprises p-type amorphous silicon.

According to an exemplary embodiment of the present disclosure, the first photosensitive sub-layer comprises a first through-hole and the second photosensitive sub-layer comprises a second through-hole, an orthographic projection of the first through-hole on the base substrate at least partially overlapping with an orthographic projection of the second through-hole on the base substrate; and the fourth electrode is arranged to extend to pass through the first through-hole and the second through-hole to connect with the first electrode.

According to an exemplary embodiment of the present disclosure, both the first through-hole and the second through-hole have their respective diameters tapering in a direction facing towards the base substrate, with inner walls of the first through-hole and the second through-hole transiting smoothly therebetween.

According to an exemplary embodiment of the present disclosure, respective inner walls of the first through-hole and the second through-hole interface with each other and transit therebetween smoothly, at one and the same tilting degree relative to the base substrate.

According to an exemplary embodiment of the present disclosure, a material for preparing the first electrode and the fourth electrode comprises: a transparent electrically-conductive material; and a material for preparing the second electrode comprises silver or aluminum.

According to an exemplary embodiment of the present disclosure, the third electrode and the second electrode are formed into one and the same electrode.

According to another aspect of the exemplary embodiment of the present disclosure, there is provided a method for preparing an OLED display substrate, comprising: providing a base substrate; and forming a photosensitive structure layer on the base substrate, the photosensitive structure layer being configured to convert an optical energy of light rays incident on the OLED display substrate into an electric energy, and in turn to provide an OLED device layer with the electric energy to drive the OLED display substrate to emit light rays, and to indicate an intensity of the light rays irradiating onto the OLED display substrate by a luminance displayed by the OLED display substrate.

According to an exemplary embodiment of the present disclosure, the method further comprises: forming an OLED device layer on the photosensitive structure layer, the OLED device layer being located on a side of the photosensitive structure layer facing away from the base substrate, and being configured to be driven by the electrical energy provided by the photosensitive structure layer to emit the light rays.

According to an exemplary embodiment of the present disclosure, the step of ‘forming a photosensitive structure layer on the base substrate’ comprises: forming a first electrode on the base substrate; forming a photosensitive layer on a side of the first electrode facing away from the base substrate; and forming a second electrode on a side of the photosensitive layer facing away from the base substrate.

According to an exemplary embodiment of the present disclosure, the step of ‘forming an OLED device layer on the photosensitive structure layer’ comprises: forming an organic light-emitting layer on a side of the second electrode facing away from the base substrate; and forming a fourth electrode on a side of the organic light-emitting layer facing away from the base substrate.

According to still another aspect of the exemplary embodiment of the present disclosure, there is provided an OLED display device, comprising the OLED display substrate as above.

Other features and advantages of the embodiments of the present disclosure will be set forth in the following description, and they will be obvious in view of such a description or understood by those skilled in the art with reference to the embodiments of the present disclosure. Objectives and other advantages of the embodiments of the present disclosure can be realized and obtained by the structures particularly pointed out in the specification, the claims and the accompanying drawings.

### BRIEF DESCRIPTION OF THE DRAWINGS

The drawings are used to provide a further understanding of technical solutions of the present disclosure, and constitute a part of the specification, and they are provided to explain the technical solutions of the present disclosure with reference to the embodiments of the present disclosure, but do not form a limitation to the technical solutions of the present disclosure.

FIG. 1 illustrates a structural schematic view of an OLED display substrate according to embodiments of the disclosure;

FIG. 2 illustrates a more detailed structural schematic view of the OLED display substrate according to embodiments of the disclosure;

FIG. 3 illustrates an exemplary display effect of the OLED display substrate according to embodiments of the disclosure;

FIG. 4 illustrates another exemplary display effect of the OLED display substrate according to embodiments of the disclosure;

FIG. 5 illustrates still another exemplary display effect of the OLED display substrate according to embodiments of the disclosure;

FIG. 6 illustrates a structural schematic view of an OLED display substrate according to other embodiments of the disclosure;

FIG. 7 illustrates an equivalent circuit diagram of the OLED display substrate according to embodiments of the disclosure; and

FIG. 8 illustrates a flow chart of a method of preparing the OLED display substrate according to embodiments of the disclosure.

### DETAILED DESCRIPTION

In order to make technical purposes, technical solutions and advantages of the embodiments of the present disclosure more clear, the embodiments of the present disclosure will be described in detail below with reference to the accompanying drawings. It should be noted that the embodiments of the present disclosure and the features in the embodiments may be freely combined with each other in case of no conflicts.

Steps illustrated in the flow chart of the accompanying drawings may for example be carried out in a computer system such as one containing a group of computer executable instructions and the like. Furthermore, although logic sequences are shown in the flow chart, in some cases, the steps as illustrated or depicted may be carried out in another different sequence distinguishing from the sequence herein.

Unless otherwise defined, technical terms or scientific terms used in the embodiments of the present disclosure should be understood in terms of ordinary meaning by those skilled in the art. The terms “first”, “second” and the like used in the embodiments of the present disclosure do not denote any order, quantity, or importance, but they are merely used to distinguish different components. The word “include”, “comprise”, or the like is intended to mean that the elements or items that are present in front of such words cover the elements or items and equivalents thereof listed behind such words, without excluding other elements or items. The word “connect” or “join” and the like is not limited to physical or mechanical connections, but may include electrical connections, whether direct or indirect. “Upper”, “lower”, “left”, “right”, “top”, “bottom”, and the like are only used to indicate relative positional relationships, and when an absolute position of the described object is changed, these relative positional relationships may also change accordingly.

Respective dimension and shape of each component in the drawings are only intended to exemplarily illustrate the contents of the disclosure, rather than to demonstrate the practical dimension or proportion of components of an OLED display substrate and an OLED display device according to an embodiment of the disclosure.

According to an aspect of embodiments of the disclosure, FIG. 1 illustrates a structural schematic view of an OLED display substrate according to embodiments of the disclosure. According to a general technical concept of the embodiments of the disclosure, as illustrated, by way of example, the OLED display substrate according to embodiments of the disclosure comprises: a base substrate 10; and an OLED device layer 20 above the base substrate 10; and a photosensitive structure layer 30 interposed between the base substrate 10 and the OLED device layer 20. The OLED device layer is located on a side of the photosensitive structure layer facing away from the base substrate.

Specifically, the photosensitive structure layer 30 is configured to convert an optical energy of light rays incident on the OLED display substrate into an electric energy, and in turn to provide the OLED device layer 20 with the electric energy to drive the OLED device layer to emit light rays, and to indicate an intensity of the light rays irradiating onto the OLED display substrate by a luminance displayed by the OLED display substrate itself (i.e., essentially from the OLED device layer of the OLED display substrate). In other words, the photosensitive structure layer 30 according to embodiments of the disclosure has its effect equivalent to that of a power supply, and the electrical energy converted from the optical energy of the light rays of different intensities which irradiate onto the OLED display substrate (especially onto its photosensitive structure layer 30) may vary, resulting in different display effects exhibited by different luminance/brightness of the light rays emitted from the OLED display substrate (essentially from its OLED device layer); i.e., there may exist different respective luminance of the light rays thus emitted, which may in turn indicate varying intensities of the light rays irradiating onto the OLED display substrate.

According to embodiments of the disclosure, the light rays irradiating onto the OLED display substrate for example comprises ultraviolet and/or visible light.

According to embodiments of the disclosure, the base substrate 10 may for example be a rigid substrate or a flexible substrate. A material for preparing a rigid substrate for example comprises (but is not limited to) one or more of glass, metal foil, and the like. And a material for preparing a flexible substrate for example comprises (but is not limited to) at least one of following: polyethylene terephthalate, ethylene terephthalate, polyetheretherketone, polystyrene, polycarbonate, polyarylate, polyarylate, polyimide, polyvinyl chloride, polyethylene, textile fiber or the like.

Specifically, the OLED display substrate may for example comprise a pixel definition layer 40, which is configured to define a plurality of pixel regions. The pixel definition layer 40 is for example arranged on a side of the photosensitive structure layer 30 facing away from the base substrate 10 and extending into the OLED device layer 20 so as to divide/delimit regions of different pixels within the OLED device layer 20.

According to embodiments of the disclosure, a material for preparing the pixel definition layer may for example comprise: a black or colored organic colloid which may absorb light, e.g., a photo-polymerization photosensitive resin or a photo-composite photosensitive resin, certainly may additionally or alternatively for example comprise other insulative composite materials, without limiting herein in embodiments of the disclosure. In addition, if the material for preparing the pixel definition layer is chosen to be a black organic colloid, then a display contrast may be enhanced.

To sum up, the OLED display substrate according to embodiments of the disclosure may for example comprise: the base substrate and the OLED device layer above the base substrate; and the photosensitive structure layer between the base substrate and the OLED device layer. The photosensitive structure layer is configured to convert an optical energy of light rays incident on the OLED display substrate into an electric energy, and in turn to provide the OLED device layer with the electric energy to drive the OLED device layer to emit light rays, and to indicate an intensity of the light rays irradiating onto the OLED display substrate by a luminance displayed by the OLED device layer of the OLED display substrate. In embodiments of the disclosure, the photosensitive structure layer is provided in the OLED display substrate, and is configured to convert the optical energy of light rays incident on the OLED display substrate into electric energy and in turn to provide the OLED device layer with the electric energy, so as to indicate an intensity of the light rays (for example, outdoor light rays) irradiating onto the OLED display substrate by a luminance displayed by OLED, for intuitively alerting people to take precautions.

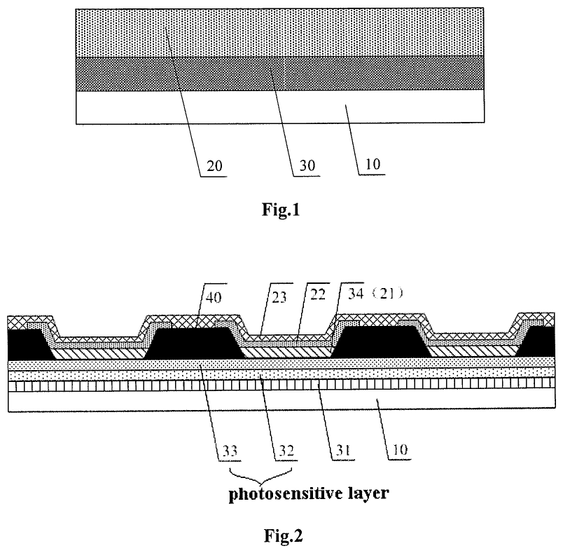

According to embodiments of the disclosure, FIG. 2 illustrates a more detailed structural schematic view of the OLED display substrate according to embodiments of the disclosure. As illustrated in FIG. 2, the photosensitive structure layer within the OLED display substrate according to an embodiment of the disclosure for example comprises: a first electrode 31, a photosensitive layer and a second electrode 34.

Specifically, the first electrode 31 is provided on a side of the base substrate 10; the photosensitive layer is provided on a side of the first electrode 31 facing away from the base substrate 10; and the second electrode 34 is provided on a side of the photosensitive layer facing away from the base substrate 10.

As illustrated in FIG. 2, the photosensitive layer comprises a first photosensitive sub-layer 32 and a second photosensitive sub-layer 33. The second photosensitive sub-layer 33 is provided on a side of the first photosensitive sub-layer 32 facing away from or facing towards the base substrate 10. It should be noticed that, in FIG. 2, it illustrates by taking a condition in which the second photosensitive sub-layer 33 is provided on a side of the first photosensitive sub-layer 32 facing away from the base substrate as an example, without applying any limitation thereon in embodiments of the disclosure.

Specifically, each of an orthographic projection of the first photosensitive sub-layer 32 on the base substrate 10 and an orthographic projection of the second photosensitive sub-layer 33 on the base substrate 10 covers an orthographic projection of the second electrode 34 on the base substrate, and each of the orthographic projection of the first photosensitive sub-layer 32 on the base substrate 10 and the orthographic projection of the second photosensitive sub-layer 33 on the base substrate 10 coincides with an orthographic projection of the first electrode 34 on the base substrate.

Specifically, in order to ensure that the photosensitive structure layer may utilize the light rays irradiating onto the OLED display substrate as efficiently as possible so as to produce sufficient electrical energy to drive the OLED device layer to emit light rays, the more volumes the first photosensitive sub-layer 32 and the second photosensitive sub-layer 33 occupy, the better the effect is.

In further embodiments, by way of example, the orthographic projection of the first photosensitive sub-layer 32 on the base substrate coincides completely with the base substrate 10, and the orthographic projection of the second photosensitive sub-layer 33 on the base substrate also coincides completely with the base substrate 10.

According to embodiments of the disclosure, there may be at least one photosensitive layer. FIG. 2 illustrates by taking one photosensitive layer as an example, without applying any limitation thereon in embodiments of the disclosure. Specifically, in a condition that there may be a plurality of photosensitive layers, these photosensitive layers overlap with each other or one another, i.e., they may be laminated with each other or one another. In an implementation, the plurality of photosensitive layers may for example be constructed identically, i.e., an intermediate structure between the first electrode and the second electrode may be: a first photosensitive sub-layer, a second photosensitive sub-layer, a first photosensitive sub-layer, a second photosensitive sub-layer . . . and the like. In another implementation, adjacent ones of the plurality of photosensitive layers may have different structures respectively; more specifically, for example, an intermediate structure between the first electrode and the second electrode may be: a first photosensitive sub-layer, a second photosensitive sub-layer, a second photosensitive sub-layer, a first photosensitive sub-layer, a first photosensitive sub-layer, a second photosensitive sub-layer . . . and the like; Or alternatively, an intermediate structure between the first electrode and the second electrode may be: a first photosensitive sub-layer, a second photosensitive sub-layer, a second photosensitive sub-layer, a first photosensitive sub-layer, a second photosensitive sub-layer, a first photosensitive sub-layer . . . and the like.

According to embodiments of the disclosure, a material for preparing the first electrode 31 may be a transparent electrically-conductive material, which may comprise: Fluorine-doped Tin Oxide (abbreviated as FTO hereinafter), Indium Tin Oxide (abbreviated as ITO hereinafter), Indium-doped Zinc Oxide (abbreviated as IZO hereinafter), Aluminum Zinc Oxide (abbreviated as AZO hereinafter), nanotube, graphene and/or the like, without applying any limitation thereon in embodiments of the disclosure.

In further embodiments, for example, more specifically, a material for preparing the first electrode 31 is FTO.

According to embodiments of the disclosure, for example, a material for preparing the first photosensitive sub-layer 32 is a n-type semiconductor material, and a material for preparing the second photosensitive sub-layer 33 is a p-type semiconductor material. The n-type semiconductor material uses electrons as current carriers, while the p-type semiconductor material uses holes as current carriers.

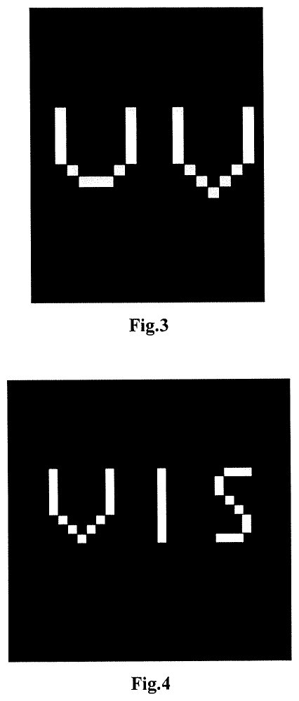

According to embodiments of the disclosure, in an implementation, the OLED display substrate may merely convert the optical energy of ultraviolet irradiating thereon (especially on the photosensitive structure layer 30 thereof) into electrical energy. FIG. 3 illustrates an exemplary display effect of the OLED display substrate according to embodiments of the disclosure; and in the OLED display substrate which exhibits the display effect as illustrated in FIG. 3, both the n-type semiconductor material and the p-type semiconductor material for preparing the first photosensitive sub-layer 32 and the second photosensitive sub-layer 33 respectively may for example be a semiconductor material having a relatively wide forbidden band so as to response to the ultraviolet. And the expression “response to the ultraviolet” means that, the optical energy of the ultraviolet irradiating on the OLED display substrate (especially on the photosensitive structure layer 30 thereof) is converted into the electrical energy. By way of example, the n-type semiconductor material comprises zinc oxide (i.e., ZnO); and the p-type semiconductor material comprises gallium nitride (i.e., GaN).

A forbidden gap (or ‘(forbidden) band gap’) of ZnO is 3.4 eV (i.e., electron volts), and an a forbidden gap of GaN is 3.44 eV, both materials being semiconductor materials having relatively wide forbidden gap.

It should be noticed that, the OLED display substrate in the implementation mainly responses to a ultraviolet having a wavelength less than 364 nanometers, and no matter how intensity of the visible light increases or changes, there may be no change thus incurred in the luminance of the light rays emitted by the OLED display substrate (essentially the OLED device layer thereof); and the display effect of the OLED display substrate may be determined by specific location at which the OLED device layer is provided, e.g., shown as characters such as ‘UV’ or the like, without applying any limitation thereon in embodiments of the disclosure. As such, the intensity of ultraviolet irradiating on the OLED display substrate (especially on the photosensitive structure layer 30 thereof) may be known depending on the intensity of the characters ‘UV’ exhibited by the light rays emitted from the OLED display substrate itself (essentially the OLED device layer thereof), so as to take precautions.

According to embodiments of the disclosure, in another implementation, the OLED display substrate may convert the optical energy of both the ultraviolet and the visible light irradiating thereon (especially on the photosensitive structure layer 30 thereof) into electrical energy. FIG. 4 illustrates another exemplary display effect of the OLED display substrate according to embodiments of the disclosure; and in the OLED display substrate which exhibits the display effect as illustrated in FIG. 4, both the n-type semiconductor material and the p-type semiconductor material for preparing the first photosensitive sub-layer 32 and the second photosensitive sub-layer 33 respectively may for example be a semiconductor material having a relatively narrower forbidden band so as to response simultaneously to both the ultraviolet and the visible light. And the expression “response simultaneously to both the ultraviolet and the visible light” means that, the optical energy of both the ultraviolet and the visible light irradiating on the OLED display substrate (especially on the photosensitive structure layer 30 thereof) may be converted into the electrical energy, simultaneously. By way of example, the n-type semiconductor material comprises n-type amorphous silicon, and the p-type semiconductor material comprises p-type amorphous silicon.

For example, a forbidden gap of the n-type amorphous silicon is 1.3 eV, and an a forbidden gap of the p-type amorphous silicon is also 1.3 eV, both materials being semiconductor materials having relatively narrower forbidden gap.

It should be noticed that, the OLED display substrate in the implementation mainly responses to both visible light and ultraviolet having a wavelength less than 953 nanometers, and the luminance of the light rays emitted by the OLED display substrate itself (essentially by the OLED device layer thereof) may be varied as long as there is an increase in the intensity of the visible light or the ultraviolet; and the display effect of the OLED display substrate may be determined by specific location at which the OLED device layer is provided, e.g., shown as characters such as NIS' or the like, without applying any limitation thereon in embodiments of the disclosure. As such, the intensity of both the visible light and the ultraviolet irradiating on the OLED display substrate (especially on the photosensitive structure layer 30 thereof) may be known depending on the intensity of the characters ‘WS’ exhibited by the light rays emitted from the OLED display substrate itself (essentially the OLED device layer thereof), so as to take precautions.

According to embodiments of the disclosure, in order to obtain more information about intensity of light rays irradiating on the OLED display substrate (especially on the photosensitive structure layer 30 thereof), in another implementation, the OLED display substrate may convert optical energy of both ultraviolet having a wavelength range and irradiating thereon, and visible light and ultraviolet having another different wavelength range and irradiating thereon into electrical energy, and indicate on different regions of the OLED display substrate respective intensities of these light rays irradiating on the OLED display substrate (especially on the photosensitive structure layer 30 thereof). FIG. 5 illustrates still another exemplary display effect of the OLED display substrate according to embodiments of the disclosure. And in the OLED display substrate which exhibits the display effect as illustrated in FIG. 5, the OLED display substrate may for example comprise a first display area labeled as ‘A1’ and a second display area labeled as ‘A2’.

Specifically, by way of example, the n-type semiconductor material and the p-type semiconductor material in the first display area A1 may be a semiconductor material having a relatively wider forbidden gap, so as to response to ultraviolet which has merely a wavelength range and irradiates on the first display area ‘A1’ of the OLED display substrate. By way of example, the n-type semiconductor material located within the first display area ‘A1’ comprises zinc oxide, and the p-type semiconductor material located within the first display area ‘A1’ comprises gallium nitride.

The forbidden gap of ZnO is 3.4 eV, and the a forbidden gap of GaN is 3.44 eV.

It should be noticed that, the first display area mainly response to a ultraviolet having a wavelength less than 364 nanometers, and no matter how the intensity of the visible light changes, there may be no change thus incurred in the luminance of the light rays emitted by the first display are of the OLED display substrate.

Specifically, by way of example, the n-type semiconductor material and the p-type semiconductor material in the second display area ‘A2’ may be a semiconductor material having a relatively narrower forbidden gap, so as to response to both visible light and ultraviolet having another different wavelength range and irradiating on the second display area ‘A1’ of the OLED display substrate. By way of example, the n-type semiconductor material located within the second display area ‘A2’ comprises n-type amorphous silicon, and the p-type semiconductor material located within the second display area ‘A2’ comprises p-type amorphous silicon.

The material of n-type amorphous silicon is an amorphous silicon material doped with V family element (i.e., group V element) such as phosphor and the like, and the material of p-type amorphous silicon is an amorphous silicon material doped with group III element such as boron and the like. For example, the forbidden gap of the n-type amorphous silicon is 1.3 eV, and the a forbidden gap of the p-type amorphous silicon is also 1.3 eV.

It should be noticed that, the second display area mainly response to both visible light and ultraviolet having a wavelength less than 953 nanometers, and the luminance of the light rays emitted by the second display area may be varied as long as there is an increase in the intensity of the visible light and/or the intensity of the ultraviolet.

It should be noticed that, the display effect of the OLED display substrate may be determined by specific location at which the OLED device layer is provided, e.g., shown as characters such as ‘UV’ and NIS' and the like, without applying any limitation thereon in embodiments of the disclosure. As such, the intensity of the ultraviolet having a wavelength range and irradiating on the OLED display substrate (especially on the OLED device layer thereof) may be known depending on the intensity of the characters ‘UV’ exhibited by the light rays emitted from the OLED display substrate itself (essentially the OLED device layer thereof), and the intensity of both visible light and ultraviolet having another different wavelength range and irradiating on the OLED display substrate (especially on the OLED device layer thereof) may be known depending on the intensity of the characters NIS' exhibited by the light rays emitted from the OLED display substrate itself (essentially the OLED device layer thereof), so as to take precautions.

According to embodiments of the disclosure, by way of example, a material for preparing the second electrode 34 comprises: silver, aluminum, and an alloy thereof.

In further embodiments, by way of example, the material for preparing the second electrode 34 is silver or aluminum.

Specifically, returning to FIG. 2, e.g., the OLED device layer in the OLED display substrate according to embodiments of the disclosure comprises: a third electrode 21, an organic light-emitting layer 22 and a fourth electrode 23.

Specifically, the fourth electrode 23 is provided above a side of the third electrode 21 facing away from the base substrate, and the organic light-emitting layer 22 is additionally interposed between the third electrode 21 and the fourth electrode 23.

By way of example, the third electrode 21 may be anodes, and anodes of adjacent pixel regions may be separated by the pixel definition layer 40 extending respectively into the OLED device layer 20; and the fourth electrode 23 may be a cathode located to cover all other layers of the entire OLED display substrate.

In order to decrease manufacturing cost for the OLED display substrate, in embodiments of the disclosure, for example, the third electrode 21 and the second electrode 34 are formed as one and the same electrode; in other words, the OLED device layer and the photosensitive structure layer share an electrode.

According to embodiments of the disclosure, by way of example, a material for preparing the fourth electrode 23 may be a transparent electrically-conductive material, which may comprise: Fluorine-doped Tin Oxide (abbreviated as HO hereinafter), Indium Tin Oxide (abbreviated as ITO hereinafter), Indium-doped Zinc Oxide (abbreviated as IZO hereinafter), Aluminum Zinc Oxide (abbreviated as AZO hereinafter), nanotube, graphene and/or the like, without applying any limitation thereon in embodiments of the disclosure.

It should be noticed that, in order to ensure that the photosensitive structure layer and the OLED device layer may cooperate with each other to form a complete loop circuit, an orthographic projection of the fourth electrode 23 on the base substrate 10 coincides completely with an orthographic projection of the first electrode 31 on the base substrate 100; i.e., the orthographic projection of the fourth electrode 23 on the base substrate 10 coincides completely with the base substrate 10.

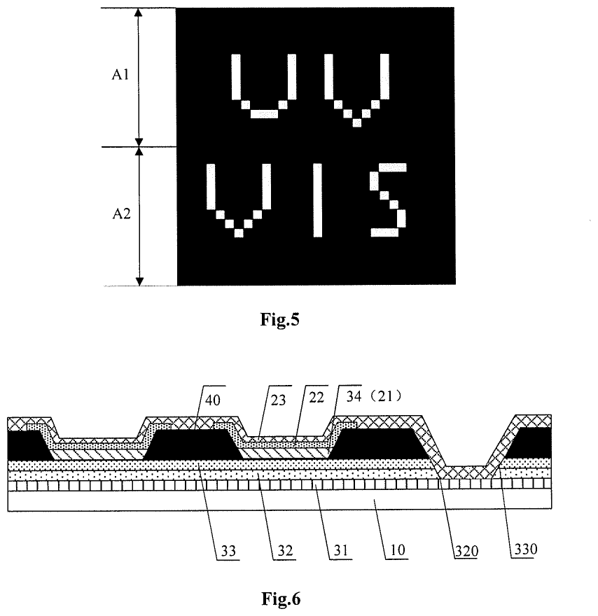

According to embodiments of the disclosure, FIG. 6 illustrates a structural schematic view an OLED display substrate according to other embodiments of the disclosure. As illustrate in FIG. 6, in order to ensure that the photosensitive structure layer and the OLED device layer may cooperate with each other to form a complete loop circuit, the first photosensitive sub-layer 32 has a first through-hole 320 which is formed to pass therethrough and the second photosensitive sub-layer 33 has a second through-hole 330 which is formed to pass therethrough, an orthographic projection of the first through-hole 320 on the base substrate at least partially overlapping with an orthographic projection of the second through-hole 330 on the base substrate. For example, as illustrated in FIG. 6, both the first through-hole 320 and the second through-hole 330 have their respective diameters tapering in a direction facing towards the base substrate 10, with inner walls of the first through-hole 320 and the second through-hole 330 transiting smoothly therebetween; and more specifically, as illustrated, respective inner walls of the first through-hole 320 and the second through-hole 330 interface with each other and transit therebetween smoothly, at one and the same tilting degree relative to the base substrate 10. And the fourth electrode 23 is in turn arranged to extend to pass through the first through-hole 320 and the second through-hole 330 to connect with the first electrode 31.

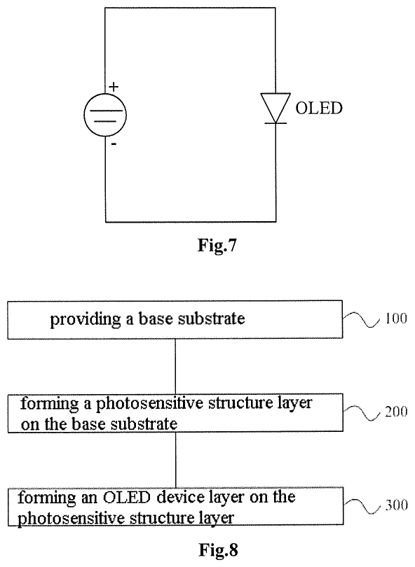

FIG. 7 illustrates an equivalent circuit diagram of the OLED display substrate according to embodiments of the disclosure. As illustrated in FIG. 7, the photosensitive structure layer within the OLED display substrate may be considered as equivalent to a power supply, and the character ‘OLED’ as labeled refers to the OLED device layer. Specifically, in view of FIG. 7, the photosensitive structure layer is for example formed by a semiconductor material; more specifically, since the first photosensitive sub-layer is formed by the n-type semiconductor material having electrons as current carriers and the second photosensitive sub-layer is formed by the p-type semiconductor material having holes as current carriers. And an operation principle of the photosensitive structure layer lies in that, in a condition that the optical energy of the light rays irradiating on the OLED display substrate is larger than the forbidden gaps of the semiconductor materials, then, electron-hole pairs may be created within respective energy bands thereof; and electron carriers and hole carriers may be driven to move by a build-in electrical field, such that electro-dynamic potentials (i.e., electromotive forces) are created respectively at both ends of the first photosensitive sub-layer and the second photosensitive sub-layer. Once a load (i.e., the ‘OLED’ as illustrated) is switched on, then the OLED starts to emit light rays; and with an increase in the intensity of light irradiating on the photosensitive structure layer, an output power of the photosensitive structure layer also increases and a light-emitting luminance of the OLED in turn increases.

According to another aspect of embodiments of the disclosure, based on the inventive concept of aforementioned embodiments, a method for preparing an OLED display substrate is also provided according to embodiments of the disclosure. FIG. 8 illustrates a flow chart of a method of preparing the OLED display substrate according to embodiments of the disclosure. As illustrated in FIG. 8, the method for preparing the OLED display substrate according to embodiments of the disclosure may for example specifically comprise following steps:

Step 100, providing a base substrate.

Step 200, forming a photosensitive structure layer on the base substrate.

The photosensitive structure layer is configured to convert an optical energy of light rays incident on the OLED display substrate into an electric energy, and in turn to provide the OLED device layer with the electric energy to drive the OLED display substrate to emit light rays, and to indicate an intensity of the light rays irradiating onto the OLED display substrate by a luminance displayed by the OLED display substrate itself.

According to embodiments of the disclosure, the light rays irradiating onto the OLED display substrate comprises ultraviolet and/or visible light.

Specifically, the step 200 specifically comprises: forming a first electrode on the base substrate; forming a photosensitive layer on a side of the first electrode facing away from the base substrate; and forming a second electrode on a side of the photosensitive layer facing away from the base substrate

The step of “forming a photosensitive layer on a side of the first electrode facing away from the base substrate” comprises: forming the first photosensitive sub-layer and the second photosensitive sub-layer on the first electrode, the second photosensitive sub-layer being provided on a side of the first photosensitive sub-layer facing away from or facing towards the base substrate.

According to embodiments of the disclosure, a material for preparing the first photosensitive sub-layer is a n-type semiconductor material, and a material for preparing the second photosensitive sub-layer is a p-type semiconductor material.

the method for preparing the OLED display substrate according to embodiments of the disclosure may for example further comprise:

Step 300, forming an OLED device layer on the photosensitive structure layer, the OLED device layer being located on a side of the photosensitive structure layer facing away from the base substrate.

Specifically, the step 300 comprises: forming an organic light-emitting layer on a side of the second electrode facing away from the base substrate; and forming a fourth electrode on a side of the organic light-emitting layer facing away from the base substrate.

The fourth electrode may be a cathode located to cover all other layers of the entire OLED display substrate.

In order to decrease a manufacturing cost for the OLED display substrate, in embodiments of the disclosure, for example, the OLED device layer and the photosensitive structure layer share a single electrode.

The method for preparing an OLED display substrate according to embodiments of the disclosure comprises: providing a base substrate; and forming a photosensitive structure layer on the base substrate, the photosensitive structure layer being configured to convert an optical energy of light rays incident on the OLED display substrate into an electric energy, and in turn to provide an OLED device layer with the electric energy to drive the OLED display substrate to emit light rays, and to indicate an intensity of the light rays irradiating onto the OLED display substrate by a luminance displayed by the OLED display substrate; and forming an OLED device layer (i.e., OLED device layer is essentially a layer of the OLED display substrate itself for emit the light rays) on the photosensitive structure layer. The OLED display substrate according to embodiments of the disclosure is provided with the photosensitive structure layer, which converts the optical energy of light rays incident on the OLED display substrate into electric energy and in turn to provide the OLED device layer with the electric energy so as to drive the OLED display substrate (essentially the OLED device layer thereof) to emit light rays displaying the contents thereof and to indicate an intensity of for example outdoor light rays irradiating onto the OLED display substrate by a luminance displayed by OLED, for intuitively alerting people to take precautions.

In addition, prior to the step of ‘forming a second electrode on a side of the photosensitive layer facing away from the base substrate’, the method further comprises: forming a pixel definition layer on the second photosensitive sub-layer, with the second electrode being about to be formed among various portions of the pixel definition layer spaced apart from one another.

The pixel definition layer projects into the OLED device layer and is configured to divide/delimit a plurality of pixel regions within the OLED device layer.

In order to ensure that the photosensitive structure layer and the OLED device layer may cooperate with each other to form a complete loop circuit, by way of example, the method for preparing an OLED display substrate according to embodiments of the disclosure further comprises: forming a first through-hole in the first photosensitive sub-layer by a laser process or a photolithography process, and forming a second through-hole in the second photosensitive sub-layer by a laser process or a photolithography process. By way of example, both the first through-hole and the second through-hole have their respective diameters tapering in a direction facing towards the base substrate, for example with inner walls of the first through-hole and the second through-hole transiting smoothly therebetween; and more specifically, respective inner walls of the first through-hole and the second through-hole interface with each other and transit therebetween smoothly, at one and the same tilting degree relative to the base substrate.

And the fourth electrode in turn extends to pass through the first through-hole and the second through-hole to connect with the first electrode.

According to still another aspect of embodiments of the disclosure, based on the inventive concept of aforementioned embodiments, an OLED display device is also provided according to embodiments of the disclosure, comprising an OLED display substrate.

The OLED display substrate here may be aforementioned OLED display substrate provided in above embodiments, with similar operation principle and effects, without being repeated herein once again.

And the OLED display substrate has a width of 5-8 cm, and a length of 10-20 cm, without being specifically restricted herein in embodiments of the disclosure.

Specifically, the OLED display device according to embodiment of the disclosure may be used to manufacture a drop indicator or be bonded to a surface of a window glass so as to indicate the intensity of outdoor light rays for intuitively alerting people to take precautions.

As compared with relevant art, embodiments of the disclosure have beneficial effects as below:

An OLED display substrate and a method for preparing the same, and an OLED display device are provided in embodiments of the disclosure. The OLED display substrate comprises: a base substrate; an OLED device layer above the base substrate; and a photosensitive structure layer interposed between the base substrate and the OLED device layer; the OLED device layer being located on a side of the photosensitive structure layer facing away from the base substrate. The photosensitive structure layer is configured to convert an optical energy of light rays irradiating on the OLED display substrate into an electric energy, and in turn to provide the OLED device layer with the electric energy to drive the OLED device layer to emit light rays, and to indicate an intensity of the light rays irradiating onto the OLED display substrate by a luminance displayed by the OLED display substrate itself. The OLED display substrate according to embodiments of the disclosure is provided with the photosensitive structure layer, which is configured to convert the optical energy of the light rays irradiating on the OLED display substrate into the electric energy and in turn to provide the OLED device layer with the electric energy so as to drive the OLED display substrate (essentially the OLED device layer thereof) to emit light rays to display contents thereof, and to indicate the intensity of for example outdoor light rays irradiating onto the OLED display substrate by a luminance displayed by OLED, for intuitively alerting people to take precautions.

The accompanying drawings of the disclosure merely relate to specific structures which are involved in embodiments of the disclosure, while other structures which are emitted from depiction may refer to relevant design.

For clarity, in accompanying drawings for depicting embodiments of the disclosure, both thickness and other dimensions of the layers and micro-structures may be scaled up. It may be understood that, once an element such as a layer, a membrane, a region or a substrate and the like are referred to as being located “above” or “below” another element, the element may be located “directly/immediately” on or under said another element, or there may exist an intermediate element therebetween.

Features in embodiments of the disclosure may be combined with each other or one another, without conflict therebetween or thereamong, so as to obtain new embodiments.

Although the embodiments disclosed in the present disclosure are as described above, their contents are merely provided to facilitate the understanding of the present disclosure, and are not intended to limit the present disclosure. Any modifications and variations may be made to forms and details of implementation by those skilled in the art in terms of form and detail without departing from the spirit and scope of the present disclosure, but the scope of the present disclosure is defined by the appended claims.

What is claimed is:

1. An OLED display substrate, comprising:
a base substrate;
an OLED device layer above the base substrate; and
a photosensitive structure layer between the base substrate and the OLED device layer;
wherein the photosensitive structure layer is configured to convert an optical energy of light rays incident on the OLED display substrate into an electric energy, and in turn to provide the OLED device layer with the electric energy to drive the OLED device layer to emit light rays, and to use a luminance displayed by the OLED device layer of the OLED display substrate to indicate an intensity of the light rays which are irradiating onto the OLED display substrate.

2. The OLED display substrate according to claim 1, wherein the photosensitive structure layer comprises:
a first electrode on a side of the base substrate;
a photosensitive layer on a side of the first electrode facing away from the base substrate; and
a second electrode on a side of the photosensitive layer facing away from the base substrate.

3. The OLED display substrate according to claim 2, wherein the photosensitive layer further comprises:
a first photosensitive sub-layer; and
a second photosensitive sub-layer on a side of the first photosensitive sub-layer facing away from or facing towards the base substrate.

4. The OLED display substrate according to claim 3, wherein the OLED device layer comprises:
a third electrode, the third electrode being formed on a side of the photosensitive structure layer facing away from the base substrate;
a fourth electrode above a side of the third electrode facing away from the base substrate; and
an organic light-emitting layer between the third electrode and the fourth electrode.

5. The OLED display substrate according to claim 4, wherein each of an orthographic projection of the first photosensitive sub-layer on the base substrate and an orthographic projection of the second photosensitive sub-layer on the base substrate coincides with an orthographic projection of the first electrode on the base substrate, and an orthographic projection of the fourth electrode on the base substrate coincides with an orthographic projection of the first electrode on the base substrate.

6. The OLED display substrate according to claim 3, wherein a material for preparing the first photosensitive sub-layer is a n-type semiconductor material, and a material for preparing the second photosensitive sub-layer is a p-type semiconductor material.

7. The OLED display substrate according to claim 6, wherein the n-type semiconductor material comprises zinc oxide; and the p-type semiconductor material comprises gallium nitride.

8. The OLED display substrate according to claim 6, wherein the n-type semiconductor material comprises n-type amorphous silicon; and the p-type semiconductor material comprises p-type amorphous silicon.

9. The OLED display substrate according to claim 6, wherein the OLED display substrate comprises a first display area and a second display area;
the n-type semiconductor material located within the first display area comprises zinc oxide, and the p-type semiconductor material located within the first display area comprises gallium nitride; the n-type semiconductor material located within the second display area comprises n-type amorphous silicon, and the p-type semiconductor material located within the second display area comprises p-type amorphous silicon.

10. The OLED display substrate according to claim 3, wherein the first photosensitive sub-layer comprises a first through-hole and the second photosensitive sub-layer comprises a second through-hole, an orthographic projection of the first through-hole on the base substrate at least partially overlapping with an orthographic projection of the second through-hole on the base substrate; and
the fourth electrode is arranged to extend to pass through the first through-hole and the second through-hole to connect with the first electrode.

11. The OLED display substrate according to claim 10, wherein both the first through-hole and the second through-hole have their respective diameters tapering in a direction facing towards the base substrate, with inner walls of the first through-hole and the second through-hole transiting smoothly therebetween.

12. The OLED display substrate according to claim 11, wherein respective inner walls of the first through-hole and the second through-hole interface with each other and transit therebetween smoothly, at one and the same tilting degree relative to the base substrate.

13. The OLED display substrate according to claim 4, wherein a material for preparing the first electrode and the fourth electrode comprises: a transparent electrically-conductive material; and
a material for preparing the second electrode comprises silver or aluminum.

14. The OLED display substrate according to claim 4, wherein the third electrode and the second electrode are formed into one and the same electrode.

15. A method for preparing an OLED display substrate, comprising:
providing a base substrate; and
forming a photosensitive structure layer on the base substrate, the photosensitive structure layer being configured to convert an optical energy of light rays incident on the OLED display substrate into an electric energy, and in turn to provide an OLED device layer with the electric energy to drive the OLED display substrate to emit light rays, and to indicate an intensity of the light rays irradiating onto the OLED display substrate by a luminance displayed by the OLED display substrate.

16. The method according to claim 15, further comprising:
forming an OLED device layer on the photosensitive structure layer, the OLED device layer being located on a side of the photosensitive structure layer facing away from the base substrate, and being configured to be driven by the electrical energy provided by the photosensitive structure layer to emit the light rays.

17. The method according to claim 15, wherein the step of ‘forming a photosensitive structure layer on the base substrate’ comprises:
forming a first electrode on the base substrate;
forming a photosensitive layer on a side of the first electrode facing away from the base substrate; and
forming a second electrode on a side of the photosensitive layer facing away from the base substrate.

18. The method according to claim 17, wherein the step of ‘forming an OLED device layer on the photosensitive structure layer’ comprises:
forming an organic light-emitting layer on a side of the second electrode facing away from the base substrate; and
forming a fourth electrode on a side of the organic light-emitting layer facing away from the base substrate.

19. An OLED display device, comprising the OLED display substrate according to claim 1.
